(19) United States
(12) Patent Application Publication
(10) Pub. No.: US 2026/0005109 A1
(43) Pub. Date: Jan. 1, 2026

(54) DEVICE, METHOD AND SYSTEM FOR SUPPORTING A GLASS SUBSTRATE WITH A FRAME STRUCTURE

(71) Applicant: Intel Corporation, Santa Clara, CA (US)

(72) Inventors: Hanyu Song, Chandler, AZ (US); Bai Nie, Chandler, AZ (US); Yonggang Li, Chandler, AZ (US); Fanyi Zhu, Gilbert, AZ (US); Srinivas Pietambaram, Chandler, AZ (US); Jefferson Kaplan, Chandler, AZ (US); Jianyong Mo, Chandler, AZ (US)

(73) Assignee: Intel Corporation, Santa Clara, CA (US)

(21) Appl. No.: 18/759,346

(22) Filed: Jun. 28, 2024

(51) Int. Cl. H01L 23/495; H01L 21/02; H01L 23/31; H01L 23/48

(52) U.S. Cl. CPC H01L 23/49582; H01L 21/02422; H01L 23/3142; H01L 23/481

(57) ABSTRACT

Techniques and mechanisms for a frame structure to be coupled to mechanically support a glass substrate. In some embodiments, a substrate comprises a glass material which forms an exterior edge, wherein one or more conductive vias variously extend through the glass material. The exterior edge is proximate to an interior edge of a frame structure which comprises one or more metal layers. Coupling of the substrate with the frame structure includes or is otherwise facilitated by a beam of laser light being directed at least to the exterior edge. In another embodiment, the beam of laser light welds the glass material to a metal of the frame, or forms a curved surface of the exterior edge, which increases surface area to improve adhesion of the glass material with other structures.

### BACKGROUND

### 1. Technical Field

This disclosure generally relates to integrated circuitry and more particularly, but not exclusively, to structures which mechanically support an optical substrate.

### 2. Background Art

IC dies may include logic, memory, or other types of circuitry. One or more IC dies may be assembled by a flip-chip assembly on to a surface of a package substrate of an IC package. A package substrate may include a core on which alternating layers of metallic conductive patterns and dielectric layers are built. The core material may be a polymer-based laminate, ceramic, silicon, or glass.

Substrates with glass cores provide several advantages as compared to other core materials, including good electrical properties and a coefficient of thermal expansion (CTE) similar to that of silicon IC dies. While glass has significant advantages when used as a core for an IC package substrate, it presents various challenges due to its brittleness.

### BRIEF DESCRIPTION OF THE DRAWINGS

The various embodiments of the present invention are illustrated by way of example, and not by way of limitation, in the figures of the accompanying drawings and in which:

FIG. 1 shows an exploded view diagram illustrating features of a system comprising a glass substrate and a supportive frame structure according to an embodiment.

FIG. 2 shows a flow diagram illustrating features of a method to support a glass substrate with a frame structure according to an embodiment.

FIGS. 3A through 3F are cross-sectional side view diagrams each showing structures during a respective one of multiple stages of processing to couple a frame structure with a glass substrate according to an embodiment.

FIGS. 4 and 5 show cross-sectional side view diagrams each illustrating features of a respective device which supports a glass substrate in a frame structure to a corresponding embodiment.

FIG. 6 shows a flow diagram illustrating features of a method to provide support for a glass substrate according to an embodiment.

FIGS. 7A through 7D are cross-sectional side view diagrams each showing structures during a respective one of multiple stages of processing to couple a frame structure with a glass substrate according to an embodiment.

FIG. 8 shows a detailed cross-sectional side view diagram illustrating features of a device wherein a frame structure is coupled with a glass substrate according to an embodiment.

FIG. 9 illustrates a diagram of an example data server machine employing an integrated circuit die which is coupled to a glass substrate according to an embodiment.

FIG. 10 is a block diagram of an example computing device according to an embodiment.

### DETAILED DESCRIPTION

Embodiments discussed herein variously provide techniques and mechanisms for a metallic frame structure to mechanically support a glass substrate. In some embodiments, a laser is applied to facilitate coupling of the glass substrate with the frame structure. The description herein includes numerous details to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

Reducing the footprint of transistors and other components within a package has become increasingly difficult and costly from a legacy manufacturing point of view. Alternative legacy packaging solutions include, for example, integrating heterogeneous components that include dissimilar chips with different functions into a package. These heterogeneous components may use lateral connections, or vertical connections. Although various designs for these package solutions may be quite different, the basic concept for improving package performance is to achieve chip stacking using thinned chips, and increasing input/output (I/O) density for multichip integration.

During manufacturing of such packages a temporary rigid carrier wafer, for example a glass wafer, may be used and may be based on a temporary bonding and debonding technology. The temporary rigid glass carrier wafer facilitates handling of thinned chips and of grinding dielectric materials for revealing lithography formed plated vias (LIVs). Furthermore, a low total thickness variation (TTV), for example of 10 μm or less, associated with glass facilitates a stringent via-to-pad overlay of avg+4 sigma that is less than or equal to 4 μm for fine pitch scaling up to 2/2 μm LS.

One legacy manufacturing challenge associated with the temporary bonding and debonding technology using a rigid glass carrier wafer includes warpage and/or shrinkage control after the removal of the rigid carrier. For example, after the rigid carrier is debonded after the first level interconnect (FLI) bump formation, the legacy package substrate is expected to warp due to inbuilt residual stress and coefficient of thermal expansion (CTE) mismatches between various components. For example, there are different CTEs for silicon (2.6 ppm/° C.), ABF (˜39 ppm/° C.) and copper (17 ppm/° C.). Such CTE mismatch may in turn impact the backend process for mid-level interconnect (MLI) bump formation, and also the assembly thermal-compression bonding (TCB) process.

In embodiments, this legacy manufacturing challenge may be addressed by using a glass layer as a permanent substrate core. Advantages of using a glass core include maintaining a TTV requirement of 2-3 μm, for a less than or equal to 30 μm bump pitch scaling. Although a glass core has the advantage of flatness and rigidity, glass may be fragile and/or brittle, and may be subjected to edge cracking, edge strains, or fatigue failure based on differing CTE of components, stresses applied to the glass core during singulation, TCB, and/or other handling. In embodiments, edge protection techniques described herein may be applied to glass cores, or glass layers in general, alone or as part of a substrate or a package to improve substrate reliability and package assembly yield.

In some embodiments, a support structure (referred to herein as a “frame structure”) is provided to mitigate a risk of damage due to the fragility of a glass substrate. In this particular context, “frame,” “frame structure,” and similar terms variously refer to a structure which is suitable to extend around, and be coupled (directly or indirectly) to provide mechanical support for, another structure such as a glass substrate. In some embodiments, a frame structure has a generally annular shape which forms a through-hole suitable to accommodate a glass substrate. In other embodiments, a frame structure forms a recess into which a glass substrate is to be placed, wherein the recess extends only partially into the frame structure.

In various embodiments, a laser is applied to a glass substrate to accommodate coupling with a frame structure. For example, application of such a laser is performed, in various embodiments, to shape an edge of the glass substrate and/or to weld the glass substrate to a metal of a frame structure. Parameters such as laser power, pulse duration, pulse repetition rate, depth of focus, exposure path/area, wavelength, and beam type may be set or adjusted in different embodiments. Laser pulses with durations in the picosecond or femtosecond range may be used. In some embodiments, the laser is an ultrashort (e.g., picosecond) pulsed laser and laser exposures with pulse durations in the range of 1 to 10 ps are used. In some embodiments, laser exposures have pulse energies of 500 to 2000 nJ. Pulse repetition rates of less than 250 kHz may be used. In some embodiments, laser exposures with pulse repetition rates of 105 kHz are used. In some embodiments, laser exposures with pulse repetition rates of 52 kHz are used. The term “laser,” an acronym for “light amplification by stimulated emission of radiation,” as used here includes electromagnetic radiation with wavelengths (and frequencies) beyond both ends of the visible spectrum of light: up to at least around 1 mm (or down to around 300 GHz) and down to at least around 10 nm (or up to around 30 PHz). For example, laser exposure includes exposure to infrared (IR) electromagnetic radiation. In some exemplary embodiments, laser exposure includes exposure to electromagnetic radiation with a wavelength in the near-IR range. In some embodiments, laser exposure includes exposure to electromagnetic radiation with a wavelength of around 1030 nm. In various embodiments, laser energy may be distributed along a path which is suitable to selectively form a substantially curved edge of a glass substrate. A point of focus may range from about 10% of a thickness of a glass core to approximately 100% of the core thickness depending on the desired width and depth of the desired laser-modified region.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including a glass substrate and a frame structure coupled thereto.

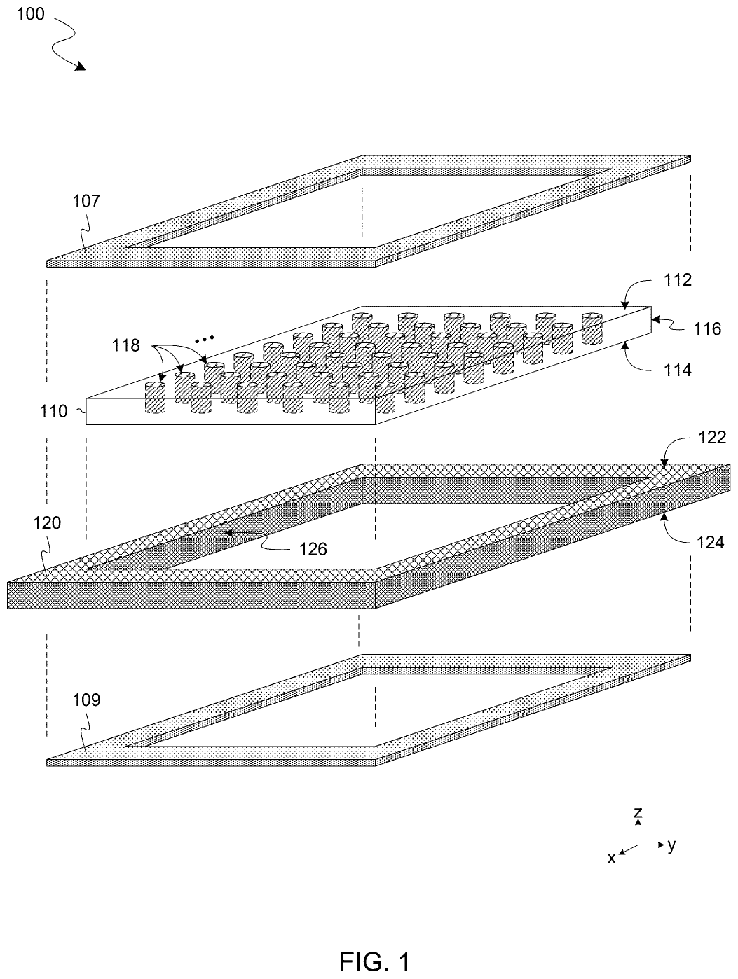

FIG. 1 shows an exploded view of a system 100 comprising a glass substrate and a supportive frame structure according to an embodiment. System 100 illustrates features of one example embodiment wherein an edge of a glass substrate is processed with a laser to facilitate coupling of the substrate with a support structure which extends around the substrate. Structures of system 100 are shown with reference to an xyz Cartesian coordinate system. Unless otherwise indicated, “length” refers herein to a dimension along the x-axis of the coordinate system, wherein “width” and “height” refer to dimension along the y-axis and the z-axis (respectively) of the coordinate system.

As shown in FIG. 1, system 100 comprises a substrate 110 and a frame 120 which is to structurally support substrate 110. In the example embodiment shown, substrate 110 includes a glass material which forms a top surface 112 and a bottom surface 114—e.g., at opposite respective sides of the substrate 110. Furthermore, the glass material forms an exterior edge structure 116 which extends between surface 112 and surface 114. In various embodiments, substrate 110 comprises a single piece of glass, or in other embodiments substrate 110 comprises two or more sections of glass that have been joined together. By way of illustration and not limitation, substrate 110 is to be a glass core of a device—such as a bridge, an interposer, or the like—which (for example) further comprises multiple build-up layers.

According to one embodiment, the term “glass” refers to an amorphous solid. Examples of glass materials that may be used with the described embodiments include pure silica (e.g., approximately 100% SiO₂), soda-lime glass, boro-silicate glass, and alumo-silicate glass. However, the disclosed embodiments are not limited to silica-based glass compositions, and glasses having alternative base materials (e.g., fluoride glasses, phosphate glasses, chalcogen glasses, etc.) may also be employed with the disclosed embodiments. Further, any combination of other materials and additives may be combined with silica (or other base material) to form a glass having desired physical properties. Examples of these additives include not only the aforementioned calcium carbonate (e.g., lime) and sodium carbonate (e.g., soda), but also magnesium, calcium, manganese, aluminum, lead, boron, iron, chromium, potassium, sulfur, and antimony, as well as carbonates and/or oxides of these and other elements. The aforementioned glasses and additives are but a few examples of the many types of materials and material combinations that may find application with the disclosed embodiments. In addition, a glass body may include surface treatments and/or coatings to improve strength and/or durability, and a glass body may also be annealed to lower internal stresses.

Generally, as used herein, the term “glass” does not refer to organic polymer materials, which may be amorphous in solid form. However, it should be understood that a glass according to some embodiments may include carbon as one of the material's constituents. For example, soda-lime glass, as well as numerous variations of this glass type, comprise carbon.

In some embodiments, any of various suitable combinations of electrical conductors extend through a (z-axis) thickness of substrate 110. By way of illustration and not limitation, system 100 further comprises one or more vias 118 which variously extend through the substrate 110 to each of the surfaces 112, 114. In an illustrative scenario according to one embodiment, system 100 is to be coupled to (or, for example, is to include) an integrated circuit die (not shown)—e.g., wherein a package comprises the integrated circuit (IC) die and system 100 for support of said IC die. Such a package includes multiple electrical connections which, for example, are to be variously coupled between the IC die and a next-level component, such as a motherboard, mainboard, or other circuit board. Furthermore, the package includes a substrate (such as substrate 110) to which the die is both mechanically and electrically coupled.

In an illustrative scenario according to one embodiment, an IC die is to be coupled to substrate 110 by an array of interconnects in a flip-chip arrangement—e.g., wherein a layer of underfill is disposed around the interconnects and between the die and substrate 110. In some embodiments, one or more interconnects each comprise, or are electrically coupled with, a respective terminal on the die (e.g., a bond pad, a copper pillar or stud bump, etc.). Alternatively or in addition, the one or more interconnects each comprise, or are electrically coupled with, a respective one of the one or more vias 118.

In one such embodiment, the IC die is to be electrically coupled, directly or indirectly, to one side of substrate 110, and a number of electrically conductive terminals (not shown) are to be electrically coupled, directly or indirectly, to an opposing side of substrate 110. Such terminals on the opposing side of substrate 110 are typically used to facilitate electrical connections with a next-level component (e.g., a circuit board), and these electrical connections can be used to deliver power to the die and to transmit input/output (I/O) signals to and from the die. The electrically conductive terminals which are to be coupled to the opposing side of substrate 110 may comprise (for example) an array pins, pads, lands, columns, bumps etc., and these terminals may be electrically coupled to a corresponding array of terminals on the circuit board or other next-level component. The terminals on the package substrate's opposing side may be coupled to the next-level board using, for example, a socket (and retention mechanism) or by a solder reflow process.

In various embodiments, frame 120 comprises a metal which is to be coupled (directly or indirectly) to the substrate 110. For example, respective metal portions of frame 120 form a top surface 122 and a bottom surface 124 on opposite respective sides of the frame 120. The frame 120 forms an interior edge structure 126 which extends between surfaces 122, 124—e.g., wherein interior edge structure 126 extends to surface 122 and at least partially to surface 124. In the example embodiment shown, interior edge structure 126 extends to surface 122 and also to surface 124, wherein frame 120 has a generally annular shape. In an alternative embodiment, interior edge structure 126 extends only partially through frame 120—e.g., wherein interior edge structure 126 extends around a recess structure of frame 120, and a base portion (not shown) of frame 120 extends under at least part of the recess structure to provide additional support for substrate 110.

In some embodiments, frame 120 is formed of a contiguous body of copper and/or any of various other suitable metals, or alloys thereof. In other embodiments, frame 120 comprises heterogeneous material layers including at least two metal layers—e.g., wherein frame 120 is a copper clad laminate (CCL). In one such embodiment, respective interior edges of one or both copper layers of an annular shaped CCL are to be coupled to exterior edge structure 116 of substrate 110.

Some embodiments facilitate mechanical support of substrate 110 with frame 120 by subjecting at least the glass of substrate 110 to a laser processing which facilitates coupling between substrate 110 and frame 120. For example, the laser processing comprises directing a laser to an interface where respective edges of substrate 110 and frame 120 adjoin each other, wherein the laser causes a glass of substrate 110 to be welded with a metal of frame 120. Alternatively or in addition, the laser processing comprises using a laser to form a curved edge of substrate 110. In one such embodiment, forming such a curved edge provides a relatively large surface area, which in turn promotes adhesion of substrate 110 to another material, such as any of various suitable dielectrics, which is to be disposed between substrate 110 and frame 120. By way of illustration and not limitation, a laser forms a substantially curved edge structure, a microroughness of which further promotes adhesion to substrate 110.

In various embodiments, one or more material layers are variously disposed—each on a respective side of substrate 110 and/or a respective side of frame 120—to seal or otherwise protect an interface region where exterior edge structure 116 and interior edge structure 126 are coupled to each other. By way of illustration and not limitation, system 100 further comprises a sealant structure 107 which extends over portions of surfaces 112, 122 and which spans the interface of edge structure 116 with edge structure 126. Alternatively or in addition, system 100 further comprises another sealant structure 109 which extends under portions of surfaces 114, 124 and which spans the interface of edge structure 116 with edge structure 126. In one such embodiment, sealant structure 107 and/or sealant structure 109 comprise any of various suitable prepreg (pre-impregnated) composite material layers which include a fiber matrix and a polymer.

In some embodiments, system 100 further comprises one or more additional structures (not shown) which facilitate coupling of via 118 with an IC die and/or with any of various next-level components. For example, such one or more additional structures comprise first build-up layers which are disposed on surface 112 and/or second build-up layers which are disposed under surface 124.

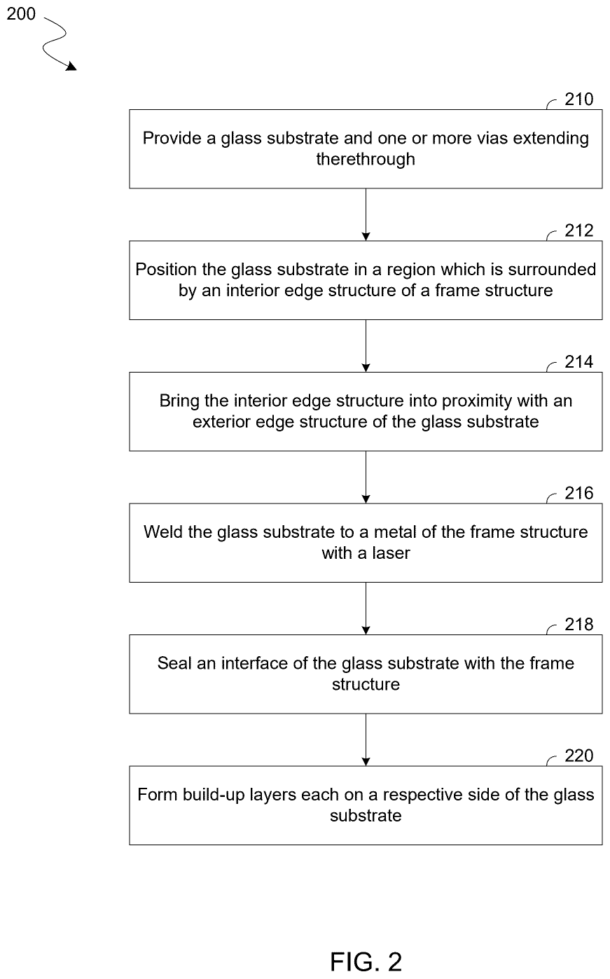

FIG. 2 shows a method 200 for supporting a glass substrate with a frame structure according to an embodiment. Method 200 illustrates one example of an embodiment wherein a laser is used to weld a metal of a supporting frame structure with a glass substrate which has one or more vias extending therein. Operations such as those of method 200 are performed, for example, to provide some or all of the structures of system 100.

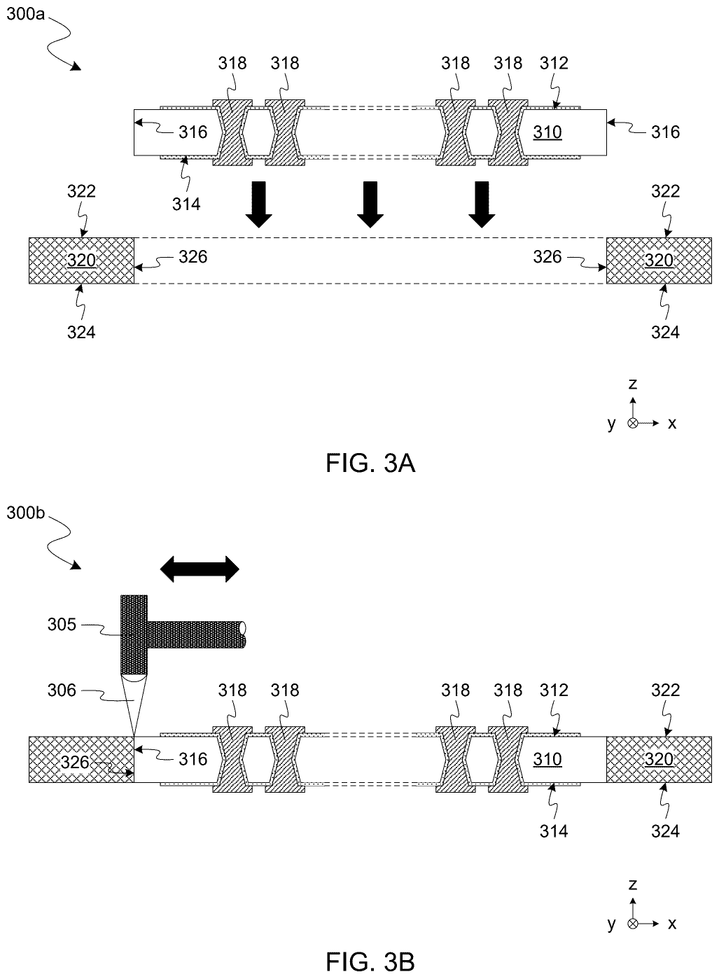

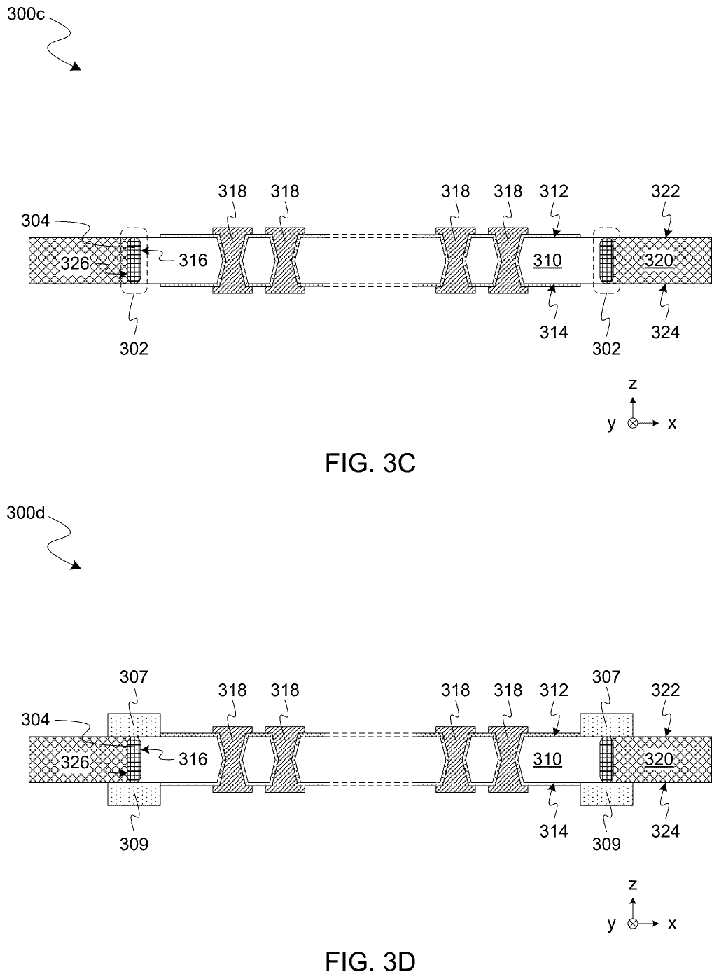

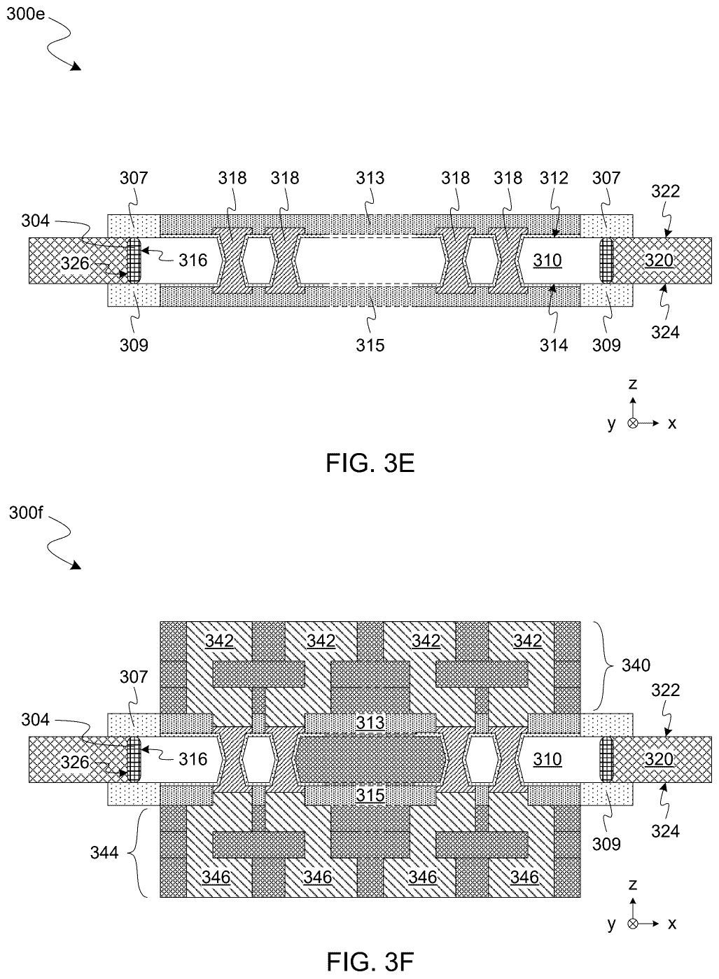

To illustrate certain features of various embodiments, method 200 is described herein with reference to processing stages 300a through 300f which are illustrated in FIGS. 3A through 3F (respectively). However, it is to be appreciated that, in other embodiments, method 200 additionally or alternatively provides structures other than those variously shown in stages 300a through 300f.

As shown in FIG. 2, method 200 comprises (at 210) providing a glass substrate and one or more vias extending therethrough. Furthermore, method 200 comprises (at 212) positioning the glass substrate in a region which is surrounded by an interior edge structure of a frame structure.

For example, FIGS. 3A through 3F are cross-sectional side view diagrams each showing structures during a respective one of multiple stages 300a through 300f of processing to couple a frame structure with a glass substrate according to an embodiment. At the stage 300a shown in FIG. 3A, a substrate 310 is positioned horizontally in a region which, below substrate 310, is surrounded by a frame 320. Substrate 310 and frame 320 correspond functionally to substrate 110 and frame 120 (respectively), for example. Substrate 310 includes a glass material which forms a top surface 312 and a bottom surface 314 at opposite respective sides of the substrate 310. The glass material forms an exterior edge structure 316 which extends between surface 312 and surface 314.

Vias 318 (such as the one or more vias 118) variously extend through the substrate 310 to facilitate electrical interconnection between surfaces 312, 314. For example, substrate 310 comprises one or more conductors and corresponding holes, or through-glass vias, that extend through the glass of substrate 310 from surface 312 to surface 314. The holes may be formed in a glass core during a casting process or may be formed after casting, e.g., by imprinting, sand blasting, laser drilling, or etching. Each conductor may be disposed in a respective hole or through-glass via. Each conductor comprises an electrically conductive material, such as metals, composite materials, and electrically conductive polymers. Suitable metals include copper, tin, silver, gold, nickel, aluminum, and tungsten, as well as alloys of these and/or other metals. Electrically conductive material may be deposited in the holes by any suitable process, such as, for example, screen printing techniques, plating techniques (electroplating or electroless plating), chemical vapor deposition (CVD), and physical vapor deposition (PVD). In an embodiment, a conductor comprises a metal wire embedded in substrate 310.

In an embodiment, respective metal portions of frame 320 form a top surface 322 and a bottom surface 324 on opposite respective sides of the frame 320. The frame 320 further forms an interior edge structure 326 which extends between (and in this example, to each of) the surfaces 322, 324. In one such embodiment, frame 320 is a contiguous metal body (e.g., comprising any of various metals such as copper, tin, nickel, aluminum, or alloys of these and/or other suitable metals) or, alternatively, comprises heterogeneous material layers including at least two metal layers—e.g., wherein frame 320 is a CCL.

Referring again to FIG. 2, method 200 further comprises (at 214) bringing the interior edge structure into proximity with an exterior edge structure of the glass substrate. Furthermore, method 200 comprises (at 216) welding the glass substrate to a metal of the frame structure with a laser. For example, at the stage 300b shown in FIG. 3B, substrate 310 is positioned within a through-hole formed at least in part by the interior edge structure 326 of frame 320. More particularly, interior edge structure 326 surrounds substrate 310, and is adjacent or otherwise proximate to the exterior edge structure 316 thereof. Subsequently, a laser device 305 is operated to direct a beam 306 of laser light at a region which comprises an interface of exterior edge structure 316 with interior edge structure 326. In one such embodiment, laser device 305 is controllably moved around a periphery of substrate 310 to weld one or more portions of exterior edge structure 316 each with an opposite portion of interior edge structure 326. At the stage 300c shown in FIG. 3C, processing with the beam 306 of laser device 305 has resulted in the formation of a weld 304 in an interface 302 of the exterior edge structure 316 with the interior edge structure 326.

Referring again to FIG. 2, method 200 further comprises (at 218) sealing an interface of the glass substrate with the frame structure. For example, at the stage 300d shown in FIG. 3D, a sealant structure 307 is adhered to or otherwise deposited on respective portions of surfaces 312, 322, wherein sealant structure 307 spans the interface 302 of exterior edge structure 316 with interior edge structure 326. Alternatively or in addition, another sealant structure 309 is adhered to or otherwise deposited on respective portions of surfaces 314, 324—e.g., wherein sealant structure 309 similarly spans interface 302. In one such embodiment, one or each of sealant structures 307, 309 is a layer of a prepreg composite, such as one used in any of various conventional semiconductor packaging technologies.

Referring again to FIG. 2, method 200 further comprises (at 220) forming build-up layers each on a respective side of the glass substrate. For example, at the stage 300e shown in FIG. 3E, a layer of a dielectric 313 has been deposited on surface 322—e.g., at least over vias 318 and, in some embodiments, to opposite interior edges of sealant structure 307. Alternatively or in addition, a layer of a dielectric 315 (e.g., having the same composition as that of dielectric 313) is deposited on surface 324—e.g., at least over vias 318 and, in some embodiments, to opposite interior edges of sealant structure 309.

At the stage 300f shown in FIG. 3F, one or more patterned mask, etch, deposition (e.g., metallization) and/or other suitable fabrication processes are performed to successively form build-up layers 340 on surface 312 and dielectric 313, wherein build-up layers 340 comprise insulator layers and patterned interconnect structures 342 variously disposed therein. Alternatively or in addition, such fabrication processes successively form build-up layers 344 on surface 314 and dielectric 315, wherein build-up layers 344 comprise insulator layers and patterned interconnect structures 346 variously disposed therein.

In a typical embodiment, there is at least one build-up layer on each of a die side of substrate 310 and a land side of substrate 310, but in some embodiments, a build-up layer is provided on only one of surfaces 312, 314. Generally, as used herein, the term “build-up” layer refers to one or more layers. While the term “build-up” layer may refer to a single dielectric layer or a single metallization layer, a build-up layer may comprise one or more dielectric layers and one or more metallization layers. A dielectric layer may comprise any suitable dielectric material (e.g., polymer materials, silicon dioxide (SiO₂), silicon nitride (Si₃N₄), etc.) and may be formed by any suitable technique (e.g., by deposition, lamination, plasma enhanced chemical vapor deposition (PECVD), etc.). A metallization layer may comprise any suitable electrically conductive metal (e.g., copper, aluminum, silver, etc.), and may be deposited by any suitable technique (e.g., plating processes, such as electroplating and electroless plating). Further, a metal layer may be patterned to form any suitable number and configuration of traces, power planes, ground planes, and other conductors to facilitate the routing of power and I/O signals. In embodiments, a build-up layer may be coupled with a power supply, e.g., a power plane or other power conductor in a metallization layer of a build-up layer may be coupled with a power supply. In some embodiments, a build-up layer may include a redistribution layer.

In some embodiments build-up layers 340 and/or interconnect structures 342 facilitate electrical coupling of vias 318 with one or more IC dies. In one such embodiment, the IC die comprises a processing system or device. For example, such an IC die may comprise a microprocessor or a graphics processor. The IC die can perform instructions from any number of processor architectures having any number of instruction formats. In one embodiment, the IC die may employ an “x86” instruction set architecture, as used by Intel Corporation. However, in other embodiments, the processor may perform instructions from other architectures or from other processor designers. For example, in some embodiments, the IC die may employ a reduced instruction set computer (RISC) architecture. In another embodiment, the IC die comprises a memory device. According to a further embodiment, the IC die comprises a system-on-chip (SoC). In yet another embodiment, the IC die may include digital circuitry, analog circuitry, or a combination of both analog and digital circuitry. However, some embodiments are not limited to a particular functionality which may be provided by such an IC die.

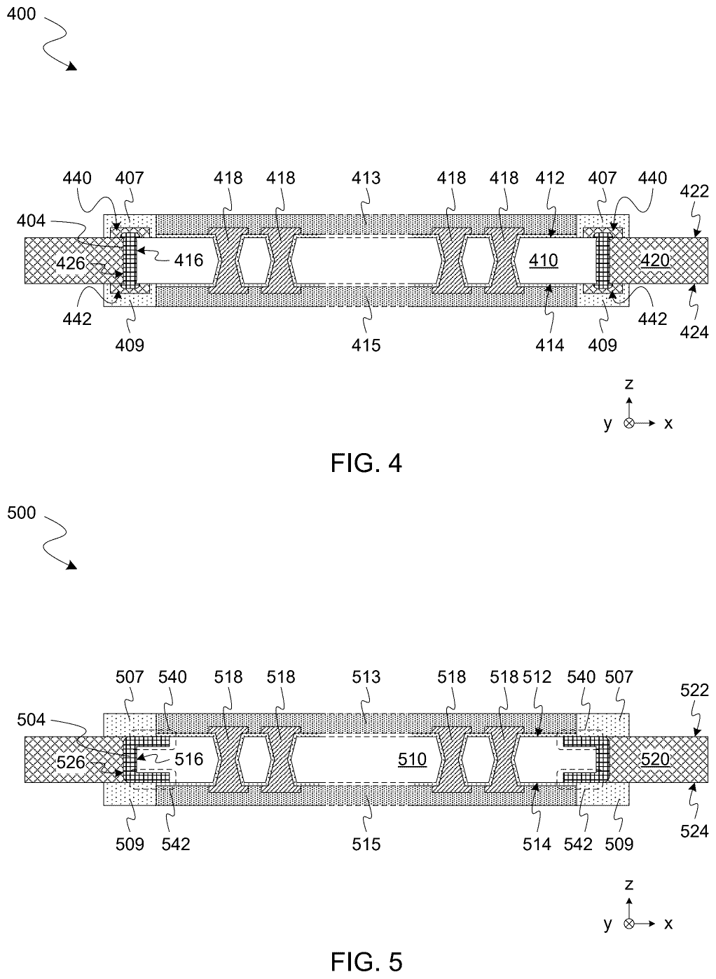

FIG. 4 shows a cross-sectional side view of a device 400 which supports a glass substrate in a frame structure to an embodiment. Device 400 illustrates features of one example embodiment which is fabricated with an additional metal deposition through which laser processing is performed to weld a glass substrate and an at least partially metal frame structure. In some embodiments, device 400 provides functionality such as that of system 100 or stage 300—e.g., wherein operations of method 200 provide structures of device 400.

As shown in FIG. 4, device 400 comprises a substrate 410 and a frame 420 which, for example, correspond functionally to substrate 110 and frame 120 (respectively). Substrate 410 comprises a glass material which forms surfaces 412, 414 on opposite respective sides of substrate 410. The glass material further forms an exterior edge structure 416 which extends to each of surfaces 412, 414. In an embodiment, vias 418 variously extend through substrate 410 to each of surfaces 412, 414—e.g., wherein vias 418 correspond functionally to vias 118 or to vias 318 (for example).

In one such embodiment, frame 420 comprises metal portions which form respective surfaces 422, 424 on opposite respective sides of frame 420—e.g., wherein an interior edge structure 426 of frame 420 extends between surfaces 422, 424. Although some embodiments are not limited in this regard, device 400 further comprises sealant structures 407, 409 and dielectrics 413, 415 which, for example, correspond functionally to sealant structures 307, 309 and dielectrics 413, 415 (respectively).

In an embodiment, fabrication of device 400 comprises laser processing to weld one or more portions of the exterior edge structure 416 each to a respective opposing portion of the interior edge structure 426—e.g., wherein such laser processing includes features of the processing illustrated by the stages 300a through 300f. Prior to such processing, additional metal is provided at a site of laser welding.

In an illustrative scenario according to one embodiment, a first metal foil (such as a copper foil, for example) is deposited on a portion of surface 412 and/or a portion of surface 422—e.g., wherein the first metal foil extends horizontally to span and/or otherwise adjoin one side of a region which comprises an interface of exterior edge structure 416 with interior edge structure 426. In an embodiment, a laser welding process comprises directing a beam of laser light toward the first metal foil and the underlying interface region. For example, the beam is moved along surfaces 412, 422 to form at least some of a weld structure 404 from the glass of substrate 410 and the metal of frame 420. In one such embodiment, the welding process results in a residual metal 440—i.e., a residue of the first metal foil-remaining on surface 412 and/or on surface 422. For example, the residual metal 440 is between a sealant structure 407 (such as sealant structure 307) and some or all of substrate 410, frame 420, and weld structure 404.

Alternatively or in addition, a second metal (e.g., copper) foil is deposited on a portion of surface 414 and/or a portion of surface 424—e.g., wherein the second metal foil extends horizontally to span and/or otherwise adjoin an opposite side of the interface region. In one such embodiment, the laser welding process additionally or alternatively comprises directing a beam of laser light toward the second metal foil and the interface region—e.g., wherein the beam is moved along surfaces 414, 424 to form at least some of the weld structure 404. Such a welding process results in a residual metal 442—i.e., a residue of the second metal foil-remaining on surface 414 and/or on surface 424. For example, the residual metal 442 is between a sealant structure 409 (such as sealant structure 309) and some or all of substrate 410, frame 420, and weld structure 404.

FIG. 5 shows a cross-sectional side view of a device 500 which supports a glass substrate in a frame structure to an embodiment. Device 500 illustrates features of one example embodiment wherein a glass substrate comprises one or more recess structures which (for example) mitigate thermal stresses during a laser welding with a metal frame. In some embodiments, device 500 provides functionality such as that of system 100—e.g., wherein operations of method 200 provide structures of device 500.

As shown in FIG. 5, device 500 comprises a substrate 510 and a frame 520 which, for example, correspond functionally to substrate 110 and frame 120 (respectively). Substrate 510 comprises a glass material which forms surfaces 512, 514 on opposite respective sides of substrate 510, and an exterior edge structure 516 which extends to each of surfaces 512, 514. Vias 518 variously extend through substrate 510 to each of surfaces 512, 514—e.g., wherein vias 518 correspond functionally to vias 118.

Frame 520 comprises metal portions which form respective surfaces 522, 524 on opposite respective sides of frame 520, wherein an interior edge structure 526 extends between surfaces 522, 524. Although some embodiments are not limited in this regard, device 500 further comprises sealant structures 507, 509 and dielectrics 513, 515 which, for example, correspond functionally to sealant structures 307, 309 and dielectrics 513, 515 (respectively).

In some embodiments, one or more recess structures are formed each with a respective one of surfaces 512, 524. By way of illustration and not limitation, a vertical recess structure 540 is formed along some or all of a periphery of surface 512, wherein the recess structure 540 extends to the region comprising an interface of exterior edge structure 516 with interior edge structure 526. Alternatively or in addition, another vertical recess structure 542 is formed along some or all of a periphery of surface 514, wherein the recess structure 542 similarly extends to the interface region. In various embodiments, recess structure 540 and/or recess structure 542 are formed with any of various suitable masked etch, laser ablation and/or other suitable subtractive processes adapted (for example) from conventional packaging techniques.

In one such embodiment, fabrication of device 500 comprises laser processing to weld one or more portions of the exterior edge structure 516 each to a respective opposing portion of the interior edge structure 526—e.g., wherein such laser processing includes features of the processing illustrated by the stages 300a through 300f. In providing recess structure 540 and/or recess structure 542 (for example), some embodiments variously prevent or otherwise mitigate thermal stresses which might otherwise result from such laser processing. For example, substrate 510 accommodates an expansion of a weld structure 504 (and/or a portion of a metal of frame 520) into recess structure 540 and/or into recess structure 542 during laser welding. As a result, directly opposite expansions of the glass of substrate 510 and the metal of frame 520 are prevented or otherwise reduced. In some embodiments, device 500 further comprises a residual metal—similar to residual metal 440 and/or residual metal 442—which extends into and/or over one or each of recess structures 540, 542.

In an illustrative scenario according to one embodiment, a horizontal (x-axis) length of recess structure 540 at one end of surface 512—or, for example, a horizontal length of recess structure 542 at one end of surface 514—is equal to or less than 200 microns (um) and, in some embodiments, less than 100 um. In one such embodiment, a vertical (z-axis) height of recess structure 540 at that same one end of substrate 510—or, for example, a vertical height of recess structure 540 at that same one end of surface 514—is equal to or less than 20 um and, in some embodiments, less than 10 um. However, such dimensions are merely illustrative, and may be different in other embodiments according to implementation-specific details.

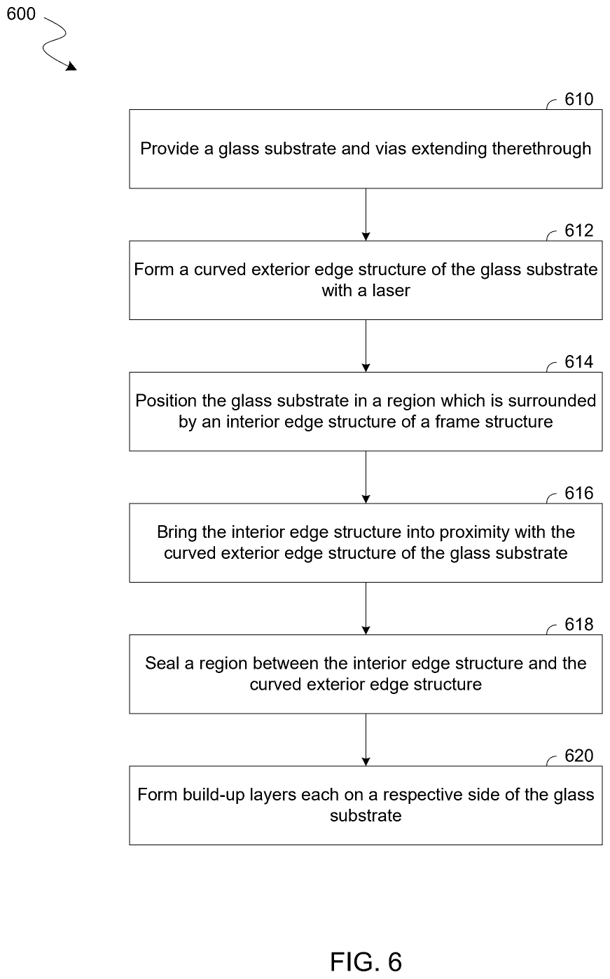

FIG. 6 shows a method 600 for providing support for a glass substrate according to an embodiment. Method 600 illustrates one example of an embodiment wherein laser processing is applied to form a curved edge of a glass substrate. In forming a curved substrate edge, some embodiments variously increase a glass surface area which, in turn, promotes adhesion of the substrate with adjoining structures.

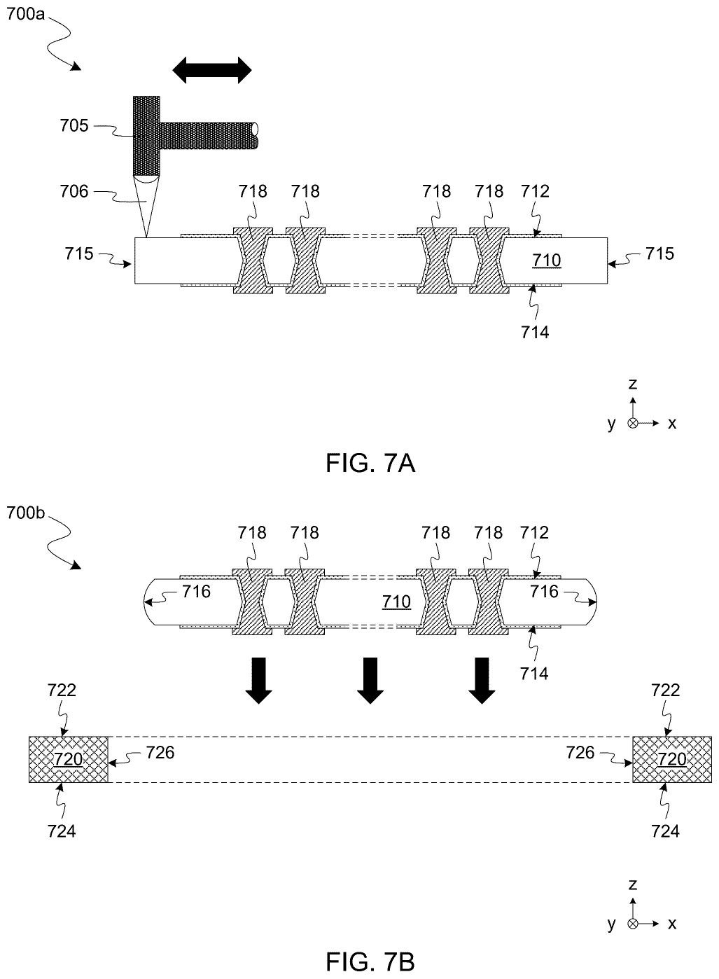

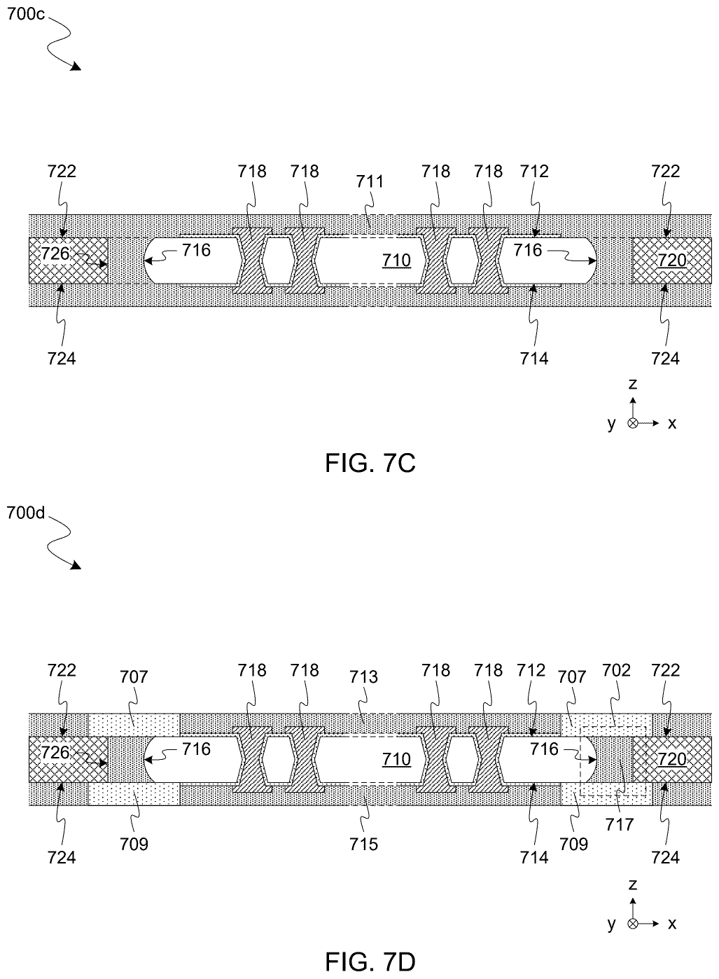

To illustrate certain features of various embodiments, method 600 is described herein with reference to processing stages 700a through 700d which are illustrated in FIGS. 7A through 7D (respectively). However, it is to be appreciated that, in other embodiments, method 600 additionally or alternatively provides structures other than those variously shown in stages 700a through 700d. In various embodiments, method 600 and/or processing such as that illustrated by stages 700a through 700d, provide structures of system 100 (for example).

As shown in FIG. 6, method 600 comprises (at 610) providing a glass substrate and vias extending therethrough. Furthermore, method 600 comprises (at 612) forming a curved exterior edge structure of the glass substrate with a laser. For example, FIGS. 7A through 7E show structures each during a respective one of multiple stages 700a through 700e of processing to couple a frame structure with a glass substrate according to an embodiment. At the stage 700a shown in FIG. 7A, a glass substrate 710 forms surfaces 712, 714 at opposite respective sides thereof, and further forms an exterior edge structure 715 which extends between surface 712 and surface 714. Vias 718 (such as vias 118) variously extend through substrate 710 to facilitate electrical interconnection between surfaces 712, 714.

In the cross-section shown for stage 700a, some or all of the exterior edge 715 is substantially flat (e.g., vertical) in the region between surfaces 712, 714. At stage 700a, a laser device 705 is operated to direct a beam 706 of laser light at a region which includes and/or is proximate to the flat exterior edge 715 of substrate 710. In one such embodiment, laser device 705 is controllably moved around a periphery of substrate 710 to selectively remove portions of the glass material which are at or near the exterior edge 715.

Referring again to FIG. 6, method 600 further comprises (at 614) positioning the glass substrate in a region which is surrounded by an interior edge structure of a frame structure. For example, at the stage 700b shown in FIG. 7B, processing with the beam 706 of laser device 705 has resulted in the formation of a curved exterior edge structure 716 from the flat edge 715 of substrate 710. Substrate 710 is positioned horizontally in a region which, below substrate 710, is surrounded by a frame 720—e.g., in preparation for substrate 710 being brought into a through-hole structure which is formed at least in part with (and, for example, is surrounded by) an interior edge structure 726 of frame 720. Substrate 710 and frame 720 correspond functionally to substrate 110 and frame 120 (respectively), for example.

Respective metal portions of frame 720 form surfaces 722, 724 on opposite respective sides of the frame 720, which further forms an interior edge structure 726 that extends to each of surfaces 722, 724. In one such embodiment, frame 720 is a contiguous metal body (e.g., comprising copper and/or any of various other suitable metals) or, alternatively, comprises heterogeneous material layers including at least two metal layers—e.g., wherein frame 720 is a CCL.

Referring again to FIG. 6, method 600 further comprises (at 616) bringing the interior edge structure into proximity with the curved exterior edge structure of the glass substrate. For example, at the stage 700c shown in FIG. 7C, substrate 710 has been brought into the through-hole structure formed by frame 720—e.g., wherein portions of curved exterior edge structure 716 are variously positioned opposite respective portions of interior edge structure 726 (and where, for example, interior edge structure 726 surrounds exterior edge structure 716). In preparation for subsequent processing to form build-up layer structures, one or more layers of a dielectric 711 have been variously deposited on surfaces 712, 714, as well as on surfaces 722, 724 and in a region which is between the edges 716, 726.

Referring again to FIG. 6, method 600 comprises (at 618) sealing a region between the interior edge structure and the curved exterior edge structure. Furthermore, method 600 comprises (at 620) forming build-up layers each on a respective side of the glass substrate. For example, at the stage 700d shown in FIG. 7D, a sealant structure 707 is adhered to or otherwise deposited on respective portions of surfaces 712, 722, and another sealant structure 709 is deposited on respective portions of surfaces 714, 724. Sealant structures 707, 709 variously extend horizontally to span a region 702 which is between the edges 716, 726.

Based on such deposition of sealant structures 707, 709 a dielectric portion 713 and a dielectric portion 715 are formed, from dielectric 711, on opposite respective sides of substrate 710. Furthermore, such deposition seals a dielectric portion 717 in the region 702 between edges 716, 726. In an embodiment, coupling of substrate 710 to frame 720 is facilitated by an adhesion of dielectric portion 717 (and, for example, an adhesion of sealant structures 707, 709) to each of curved exterior edge structure 716 and the interior edge structure 726. In one such embodiment, adhesion of substrate 710 to dielectric 717 is promoted by the curved shape of exterior edge structure 716 and, in some embodiments, by a microrough texture of exterior edge structure 716.

In some embodiments, additional patterned mask, etch, deposition (e.g., metallization) and/or other suitable fabrication processes are performed to successively form first build-up layers (not shown)—similar to build-up layers 340—on surface 712 and dielectric portion 713. Alternatively or in addition, such fabrication processes successively form second build-up layers (not shown)—similar to build-up layers 344—on surface 714 and dielectric portion 715.

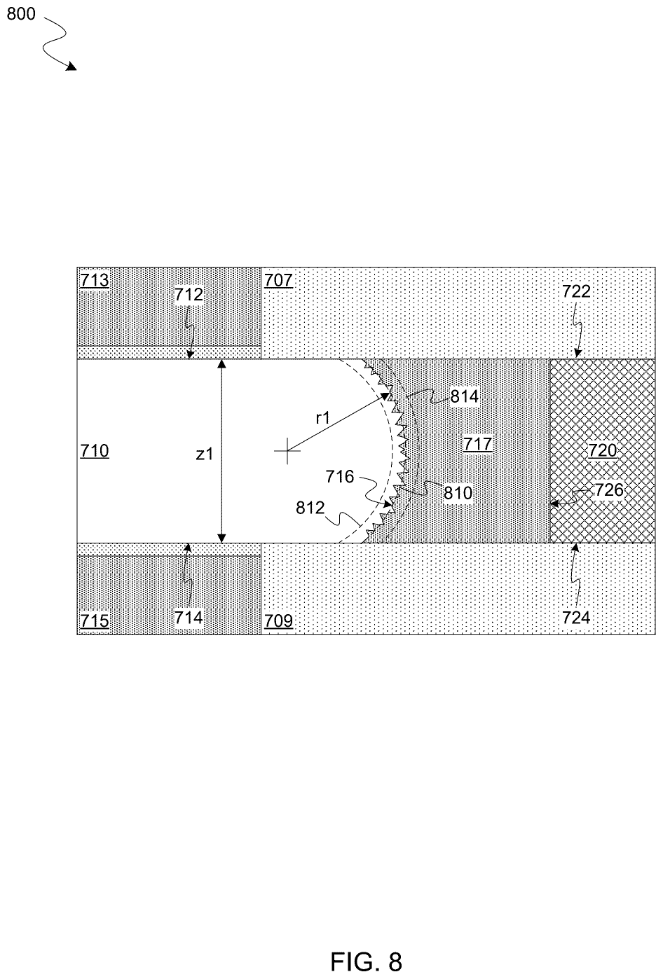

FIG. 8 shows a detailed cross-sectional side view of a device 800 comprising a frame structure which is coupled with a glass substrate according to an embodiment. Device 800 is one example of a product fabricated by the processing illustrated with stages 700a through 700d. For example, the cross-section shown for device 800 includes structures shown in region 702.

In the cross-section of detail view 800 shown in FIG. 8, at least a portion of the exterior edge structure 716 of substrate 710 substantially conforms to a curve 810 between surfaces 712, 714, wherein curve 810 has a radius r1 of curvature. By way of illustration and not limitation, the exterior edge structure 716 is between two other curves 812, 814 (which are concentric with curve 810), at least within the cross-section shown. In one such embodiment, curve 812 corresponds to a radius which is shorter than radius r1 by 5%, wherein curve 814 corresponds to another radius which is longer than radius r1 by 5%.

In an illustrative scenario according to one embodiment, the substrate 710 has a (z axis) thickness z1—between surfaces 712, surface 714—which, for example, is in a range of 400 microns (um) to 1100 um. In one such embodiment, the radius r1 of the curve 810 is less than or equal to ten times the thickness z1. By way of illustration and not limitation, the radius r1 is in a range of one half of the thickness z1 to eight times the thickness z1 (and, for example, in a range of one half of the thickness z1 to four times the thickness z1), in some embodiments.

In some embodiments, laser processing of substrate 710 to form the curved exterior edge structure 716 comprises forming a microrough texture of exterior edge structure 716. By way of illustration and not limitation, the portion of the exterior edge structure 716 which is in the cross-section shown has a roughness average (Ra) which, for example, is in a range of 5 microns (um) to 50 um. In one such embodiment, the roughness average (Ra) is in a range of 5 um to 10 um, for example. However, such possible ranges of the roughness average are merely illustrative, and may be different in other embodiments according to implementation-specific details.

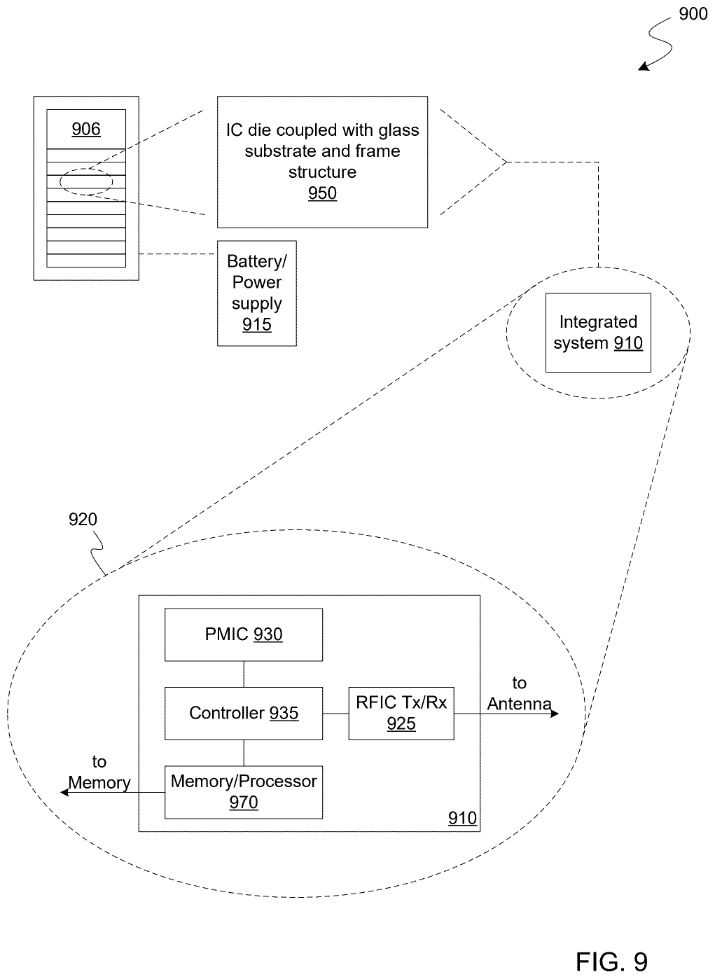

FIG. 9 illustrates a schematic of a data server machine including an IC device 900 which comprises a glass substrate and a frame structure which is coupled to support said glass substrate, in accordance with one or more embodiments described elsewhere herein. Server machine 906 may be any commercial server, for example, including any number of high-performance computing platforms disposed within a rack and networked together for electronic data processing, which in the exemplary embodiment includes one or more devices 950, an IC die of which is coupled to a glass substrate that is supported by a metal frame structure.

Also as shown, server machine 906 includes a battery and/or power supply 915 to provide power to devices 950, and to provide, in some embodiments power delivery functions such as power regulation. Devices 950 may be deployed as part of a package-level integrated system 910. Integrated system 910 is further illustrated in the expanded view 920. In the exemplary embodiment, integrated system 910 includes an integrated circuitry 970 (labeled “Memory/Processor”) includes at least one memory array (e.g., RAM), and/or at least one processor core (e.g., a microprocessor, a multi-core microprocessor, or graphics processor, or the like) having the characteristics discussed herein. In an embodiment, integrated circuitry 970 is a microprocessor disposed on a glass substrate that is supported by a metal frame structure. Integrated circuitry 970 may be further coupled to (e.g., communicatively coupled to) a board, a substrate, or an interposer along with, one or more of a power management integrated circuit (PMIC) 930, RF (wireless) integrated circuitry (RFIC) 925 including a wideband RF (wireless) transmitter and/or receiver (TX/RX) (e.g., including a digital baseband and an analog front end module further comprises a power amplifier on a transmit path and a low noise amplifier on a receive path), and a controller 935.

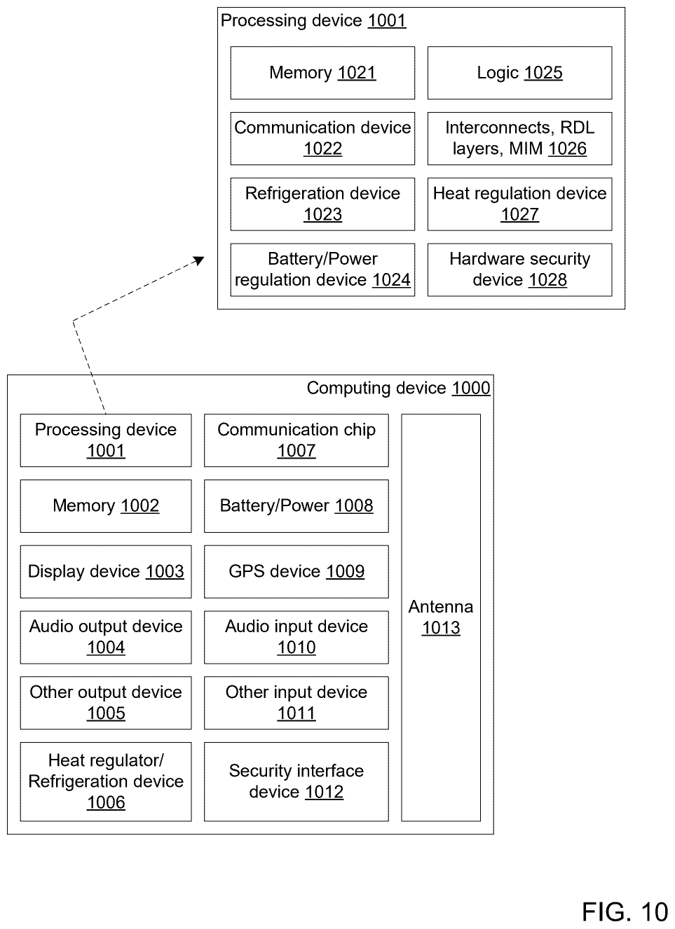

FIG. 10 is a block diagram of a computing device 1000 in accordance with some embodiments. For example, one or more components of computing device 1000 may include any of the devices or structures discussed elsewhere herein. Exemplary components are illustrated in FIG. 10 as included in computing device 1000, but any one or more of these components may be omitted or duplicated, as suitable for the application. In some embodiments, some of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled.

Computing device 1000 may include a processing device 1001 (e.g., one or more processing devices). As used herein, the term processing device or processor indicates a device that processes electronic data from registers and/or memory to transform that electronic data into other electronic data that may be stored in registers and/or memory. Processing device 1001 may include a memory 1021, a communication device 1022, a refrigeration/active cooling device 1023, a battery/power regulation device 1024, logic 1025, interconnects 1026 (i.e., optionally including redistribution layers (RDL) or metal-insulator-metal (MIM) devices), a heat regulation device 1027, and a hardware security device 1028.

Processing device 1001 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1001 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1021 includes memory that shares a die with processing device 1001. This memory may be used as cache memory and may include embedded dynamic random-access memory (eDRAM) or spin transfer torque magnetic random-access memory (STT-M RAM).

Computing device 1000 may include a heat regulation/refrigeration device 1006. Heat regulation/refrigeration device 1006 may maintain processing device 1001 (and/or other components of computing device 1000) at a predetermined low temperature during operation. This predetermined low temperature may be of various suitable temperatures adapted from conventional circuit cooling techniques.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium.

Communication chip 1007 may implement any wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project, etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 4G, 5G, and beyond. Communication chip 1007 may operate in accordance with other wireless protocols in other embodiments. Computing device 1000 may include an antenna 1013 to facilitate wireless communications and/or to receive other wireless communications (such as AM or FM radio transmissions).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a global positioning system (GPS) device 1009 (or corresponding interface circuitry, as discussed above). GPS device 1009 may be in communication with a satellite-based system and may receive a location of computing device 1000, as known in the art.

Computing device 1000 may include another output device 1005 (or corresponding interface circuitry, as discussed above). Examples include an audio codec, a video codec, a printer, a wired or wireless transmitter for providing information to other devices, or an additional storage device.

Computing device 1000 may include another input device 1011 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, managing access lists, malware detection, or spyware detection,

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

In one or more first embodiments, an electronic device comprises a substrate comprising a glass, wherein the substrate forms an exterior edge structure which extends between a first surface and a second surface at opposite respective sides of the substrate, one or more vias which each extend through the substrate to each of the first surface and the second surface, and a frame structure comprising a metal coupled to the substrate, wherein the frame structure forms an interior edge structure which extends between a third surface and a fourth surface at opposite respective sides of the frame structure, wherein an interface of the exterior edge structure with the interior edge structure comprises a weld of the glass with the metal.

In one or more second embodiments, further to the first embodiment, the electronic device further comprises a first metal residue which spans the interface and adjoins each of the first surface and the third surface.

In one or more third embodiments, further to the second embodiment, the electronic device further comprises a second metal residue which spans the interface and adjoins each of the second surface and the fourth surface.

In one or more fourth embodiments, further to the first embodiment or the second embodiment, the first surface forms a first recess structure which extends to the interface.

In one or more fifth embodiments, further to the fourth embodiment, a portion of the metal is disposed in the first recess structure.

In one or more sixth embodiments, further to the fourth embodiment, the second surface forms a second recess structure which extends to the interface.

In one or more seventh embodiments, further to the sixth embodiment, portions of the metal are disposed each in a different respective one of the first recess structure and the second recess structure.

In one or more eighth embodiments, further to the first embodiment or the second embodiment, the metal comprises copper.

In one or more ninth embodiments, further to the eighth embodiment, the frame structure comprises a copper clad laminate.

In one or more tenth embodiments, further to the first embodiment or the second embodiment, the electronic device further comprises a first sealant structure which spans the interface and which extends across respective portions of the first surface and the third surface.

In one or more eleventh embodiments, further to the tenth embodiment, the electronic device further comprises a second sealant structure which spans the interface and which extends across respective portions of the second surface and the fourth surface.

In one or more twelfth embodiments, a method comprises providing a glass substrate and one or more vias extending therethrough, positioning the glass substrate in a region which is surrounded by an interior edge structure of a frame structure, bringing the interior edge structure into proximity with an exterior edge structure of the glass substrate, welding the glass substrate to a metal of the frame structure, comprising directing a laser to an interface of the interior edge structure with the exterior edge structure.

In one or more thirteenth embodiments, further to the twelfth embodiment, the method further comprises depositing a sealant at an interface of the glass substrate with the frame structure.

In one or more fourteenth embodiments, further to the thirteenth embodiment, the method further comprises forming build-up layers each on a respective side of the glass substrate.

In one or more fifteenth embodiments, further to the twelfth embodiment or the thirteenth embodiment, the method further comprises depositing a first metal foil which spans the interface and adjoins each of the first surface and the third surface.

In one or more sixteenth embodiments, further to the fifteenth embodiment, the method further comprises depositing a second metal foil which spans the interface and adjoins each of the second surface and the fourth surface.

In one or more seventeenth embodiments, further to the twelfth embodiment or the thirteenth embodiment, the method further comprises forming in the first surface a first recess structure which extends to the interface.

In one or more eighteenth embodiments, further to the seventeenth embodiment, a portion of the metal is disposed in the first recess structure.

In one or more nineteenth embodiments, further to the seventeenth embodiment, the method further comprises forming in the second surface a second recess structure which extends to the interface.

In one or more twentieth embodiments, further to the nineteenth embodiment, portions of the metal are disposed each in a different respective one of the first recess structure and the second recess structure.

In one or more twenty-first embodiments, further to the twelfth embodiment or the thirteenth embodiment, the metal comprises copper.

In one or more twenty-second embodiments, further to the twenty-first embodiment, the frame structure comprises a copper clad laminate.

In one or more twenty-third embodiments, further to the twelfth embodiment or the thirteenth embodiment, the method further comprises forming a first sealant structure which spans the interface and which extends across respective portions of the first surface and the third surface.

In one or more twenty-fourth embodiments, further to the twenty-third embodiment, the method further comprises forming a second sealant structure which spans the interface and which extends across respective portions of the second surface and the fourth surface.

In one or more twenty-fifth embodiments, a system comprises one or more integrated circuit (IC) dies comprising a processor and a memory, a substrate comprising a glass, wherein the substrate forms an exterior edge structure which extends between a first surface and a second surface at opposite respective sides of the substrate, one or more vias which each extend through the substrate to each of the first surface and the second surface, a frame structure comprising a metal coupled to the substrate, wherein the frame structure forms an interior edge structure which extends between a third surface and a fourth surface at opposite respective sides of the frame structure, wherein an interface of the exterior edge structure with the interior edge structure comprises a weld of the glass with the metal, and build-up layers comprising interconnect structures which are variously coupled between the one or more vias and the one or more IC dies.

In one or more twenty-sixth embodiments, further to the twenty-fifth embodiment, the system further comprises a first metal residue which spans the interface and adjoins each of the first surface and the third surface.

In one or more twenty-seventh embodiments, further to the twenty-sixth embodiment, the system further comprises a second metal residue which spans the interface and adjoins each of the second surface and the fourth surface.

In one or more twenty-eighth embodiments, further to the twenty-fifth embodiment or the twenty-sixth embodiment, the first surface forms a first recess structure which extends to the interface.

In one or more twenty-ninth embodiments, further to the twenty-eighth embodiment, a portion of the metal is disposed in the first recess structure.

In one or more thirtieth embodiments, further to the twenty-eighth embodiment, the second surface forms a second recess structure which extends to the interface.

In one or more thirty-first embodiments, further to the thirtieth embodiment, portions of the metal are disposed each in a different respective one of the first recess structure and the second recess structure.

In one or more thirty-second embodiments, further to the twenty-fifth embodiment or the twenty-sixth embodiment, the metal comprises copper.

In one or more thirty-third embodiments, further to the thirty-second embodiment, the frame structure comprises a copper clad laminate.

In one or more thirty-fourth embodiments, further to the twenty-fifth embodiment or the twenty-sixth embodiment, the system further comprises a first sealant structure which spans the interface and which extends across respective portions of the first surface and the third surface.

In one or more thirty-fifth embodiments, further to the thirty-fourth embodiment, the system further comprises a second sealant structure which spans the interface and which extends across respective portions of the second surface and the fourth surface.

In one or more thirty-sixth embodiments, an electronic device comprises a substrate comprising a glass, wherein the substrate forms an exterior edge structure which extends between a first surface and a second surface at opposite respective sides of the substrate, wherein, in a cross-section of the substrate, a portion of the exterior edge structure substantially conforms to a curve, wherein a radius of the curve is less than or equal to ten times a thickness of the substrate between the first surface and the second surface, one or more vias which each extend through the substrate to each of the first surface and the second surface, and a frame structure comprising a metal coupled to the substrate, wherein the frame structure forms an interior edge structure which extends between a third surface and a fourth surface at opposite respective sides of the frame structure, a portion of a dielectric material disposed in a region between the exterior edge structure and the interior edge structure.

In one or more thirty-seventh embodiments, further to the thirty-sixth embodiment, a roughness average of the portion of the exterior edge structure is in a range of 5 microns (um) to 50 um.

In one or more thirty-eighth embodiments, further to the thirty-seventh embodiment, the roughness average is in a range of 5 um to 10 um.

In one or more thirty-ninth embodiments, further to the thirty-seventh embodiment, the thickness of the substrate between the first surface and the second surface is in a range of 400 um to 1100 um.

In one or more fortieth embodiments, further to the thirty-sixth embodiment or the thirty-seventh embodiment, the radius of the curve is in a range of one half the thickness to eight times the thickness.

In one or more forty-first embodiments, further to the fortieth embodiment, the radius of the curve is in a range of one half the thickness to four times the thickness.

In one or more forty-second embodiments, further to the thirty-sixth embodiment or the thirty-seventh embodiment, the electronic device further comprises a first sealant structure which spans the region between the exterior edge structure and the interior edge structure, and which extends across respective portions of the first surface and the third surface.

In one or more forty-third embodiments, further to the forty-second embodiment, the electronic device further comprises a second sealant structure which spans the region between the exterior edge structure and the interior edge structure, and which extends across respective portions of the second surface and the fourth surface.

In one or more forty-fourth embodiments, a method comprises providing a glass substrate and one or more vias extending therethrough, forming a curved exterior edge structure of the glass substrate with a laser, positioning the glass substrate in a region which is surrounded by an interior edge structure of a frame structure, bringing the interior edge structure into proximity with the curved exterior edge structure of the glass substrate, sealing a region between the interior edge structure and the curved exterior edge structure, forming build-up layers each on a respective side of the glass substrate.

In one or more forty-fifth embodiments, further to the forty-fourth embodiment, in a cross-section of the glass substrate, a portion of the curved exterior edge structure substantially conforms to a curve, wherein a radius of the curve is less than or equal to ten times a thickness of the glass substrate.

In one or more forty-sixth embodiments, further to the forty-fifth embodiment, the thickness of the glass substrate is in a range of 400 um to 1100 um.

In one or more forty-seventh embodiments, further to the forty-fifth embodiment, the radius of the curve is in a range of one half the thickness to eight times the thickness.

In one or more forty-eighth embodiments, further to the forty-seventh embodiment, the radius of the curve is in a range of one half the thickness to four times the thickness.

In one or more forty-ninth embodiments, further to the forty-fourth embodiment or the forty-fifth embodiment, a roughness average of a portion of the curved exterior edge structure is in a range of 5 microns (um) to 50 um.

In one or more fiftieth embodiments, further to the forty-ninth embodiment, the roughness average is in a range of 5 um to 10 um.

In one or more fifty-first embodiments, further to the forty-fourth embodiment or the forty-fifth embodiment, the method further comprises forming a first sealant structure which spans the region between the curved exterior edge structure and the interior edge structure.

In one or more fifty-second embodiments, further to the fifty-first embodiment, the method further comprises forming a second sealant structure which spans the region between the curved exterior edge structure and the interior edge structure, wherein the first sealant structure and the second sealant structure are on opposite respective sides of the glass substrate.

Techniques and architectures for providing support for circuit structures are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMS, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An electronic device comprising:
a substrate comprising a glass, wherein the substrate forms an exterior edge structure which extends between a first surface and a second surface at opposite respective sides of the substrate;
one or more vias which each extend through the substrate to each of the first surface and the second surface; and
a frame structure comprising a metal coupled to the substrate, wherein the frame structure forms an interior edge structure which extends between a third surface and a fourth surface at opposite respective sides of the frame structure, wherein an interface of the exterior edge structure with the interior edge structure comprises a weld of the glass with the metal.

2. The electronic device of claim 1, further comprising a first metal residue which spans the interface and adjoins each of the first surface and the third surface.

3. The electronic device of claim 2, further comprising a second metal residue which spans the interface and adjoins each of the second surface and the fourth surface.

4. The electronic device of claim 1, wherein the first surface forms a first recess structure which extends to the interface.

5. The electronic device of claim 4, wherein a portion of the metal is disposed in the first recess structure.

6. The electronic device of claim 4, wherein the second surface forms a second recess structure which extends to the interface.

7. The electronic device of claim 1, wherein the metal comprises copper.

8. The electronic device of claim 1, further comprising:
a first sealant structure which spans the interface and which extends across respective portions of the first surface and the third surface.

9. The electronic device of claim 8, further comprising:
a second sealant structure which spans the interface and which extends across respective portions of the second surface and the fourth surface.

10. A system comprising:
one or more integrated circuit (IC) dies comprising a processor and a memory;
a substrate comprising a glass, wherein the substrate forms an exterior edge structure which extends between a first surface and a second surface at opposite respective sides of the substrate;
one or more vias which each extend through the substrate to each of the first surface and the second surface;
a frame structure comprising a metal coupled to the substrate, wherein the frame structure forms an interior edge structure which extends between a third surface and a fourth surface at opposite respective sides of the frame structure, wherein an interface of the exterior edge structure with the interior edge structure comprises a weld of the glass with the metal; and
build-up layers comprising interconnect structures which are variously coupled between the one or more vias and the one or more IC dies.

11. The system of claim 10, further comprising a first metal residue which spans the interface and adjoins each of the first surface and the third surface.

12. The system of claim 10, wherein the first surface forms a first recess structure which extends to the interface.

13. The system of claim 10, wherein the metal comprises copper.

14. The system of claim 10, further comprising:
a first sealant structure which spans the interface and which extends across respective portions of the first surface and the third surface.

15. An electronic device comprising:
a substrate comprising a glass, wherein the substrate forms an exterior edge structure which extends between a first surface and a second surface at opposite respective sides of the substrate, wherein, in a cross-section of the substrate, a portion of the exterior edge structure substantially conforms to a curve, wherein a radius of the curve is less than or equal to ten times a thickness of the substrate between the first surface and the second surface;
one or more vias which each extend through the substrate to each of the first surface and the second surface; and
a frame structure comprising a metal coupled to the substrate, wherein the frame structure forms an interior edge structure which extends between a third surface and a fourth surface at opposite respective sides of the frame structure;
a portion of a dielectric material disposed in a region between the exterior edge structure and the interior edge structure.

16. The electronic device of claim 15, wherein a roughness average of the portion of the exterior edge structure is in a range of 5 microns (um) to 50 um.

17. The electronic device of claim 16, wherein the roughness average is in a range of 5 um to 10 um.

18. The electronic device of claim 15, wherein the radius of the curve is in a range of one half the thickness to eight times the thickness.

19. The electronic device of claim 18, wherein the radius of the curve is in a range of one half the thickness to four times the thickness.

20. The electronic device of claim 15, further comprising:
a first sealant structure which spans the region between the exterior edge structure and the interior edge structure, and which extends across respective portions of the first surface and the third surface.
